(19) United States
(12) Patent Application Publication
(10) Pub. No.: US 2019/0082559 A1
(43) Pub. Date: Mar. 14, 2019

(54) LIQUID COOLING SYSTEM WITH MULTIPLE HEAT DISSIPATION DEVICES

(71) Applicant: AURAS Technology Co., Ltd., New Taipei City (TW)

(72) Inventors: AN-CHIH WU, New Taipei City (TW); CHIH-WEI CHEN, New Taipei City (TW)

(21) Appl. No.: 15/782,187

(22) Filed: Oct. 12, 2017

(30) Foreign Application Priority Data
Sep. 8, 2017 (TW) 106130849

(51) Int. Cl. H05K 7/20; F28D 5/00

(52) U.S. Cl. CPC H05K 7/20263; F28D 5/00

(57) ABSTRACT

A liquid cooling system includes a liquid pump, a main liquid cooling head, multiple heat dissipation devices and a fan. A cooling loop is defined by the liquid pump, the main liquid cooling head and the multiple heat dissipation devices collaboratively. A working liquid flows through the liquid cooling system to facilitate heat dissipation. The fan is located beside the multiple heat dissipation devices to produce airflow to the multiple heat dissipation devices. Consequently, the heat is dissipated to the surroundings. Due to the multiple heat dissipation devices, the heat dissipating area is expanded and the hot airflow is not very concentrated. The fan produces airflow to the first heat dissipation device and the second heat dissipation devices at different positions. Consequently, the heat dissipating efficiency is enhanced.

### FIELD OF THE INVENTION

The present invention relates to a liquid cooling system, and more particularly to a liquid cooling system with multiple heat dissipation devices.

### BACKGROUND OF THE INVENTION

With increasing development of computers and various electronic devices, people in the modern societies are used to using the computers and the electronic devices for a long time. During operations of the computers and the electronic devices, a great deal of heat is generated. If the heat cannot be effectively dissipated away, some drawbacks occur. For facilitating heat dissipation, a liquid cooling system has been disclosed.

Conventionally, the liquid cooling system comprises a liquid cooling head, a liquid pump and a liquid cooling radiator. The liquid cooling radiator is a structural body comprising dense fins and a channel. Consequently, the waste heat is easily concentrated on the liquid cooling radiator and difficultly dissipated away. For increasing the cooling efficiency of the conventional liquid cooling system, the size of the liquid cooling radiator must be large enough to achieve more heat dissipating area. However, as the trends of designing the commercial electronic device is toward miniaturization, the volume and the installation space of the liquid cooling radiator are limited. In other words, the conventional liquid cooling system needs to be further improved.

### SUMMARY OF THE INVENTION

For solving the drawbacks of the conventional technologies, the present invention provides a liquid cooling system with multiple heat dissipation devices. Due to the multiple heat dissipation devices, the heat dissipating area is expanded and the hot airflow is not very concentrated to a specified site. Moreover, a fan produces airflow to a first heat dissipation device and a second heat dissipation device at different positions. Consequently, the heat dissipating efficiency is enhanced.

In accordance with an aspect of the present invention, there is provided a liquid cooling system with multiple heat dissipation devices. A working liquid flows through the liquid cooling system to facilitate heat dissipation. The liquid cooling system includes a liquid pump, a main liquid cooling head, a first heat dissipation device, a second heat dissipation device and a fan. The main liquid cooling head is in fluid communication with the liquid pump. The working liquid within the liquid pump is pumped into the main liquid cooling head by the liquid pump. Consequently, the working liquid within the main liquid cooling head exchanges heat with the main liquid cooling head. The first heat dissipation device is in fluid communication with the main liquid cooling head. The first heat dissipation device receives the working liquid from the main liquid cooling head. The second heat dissipation device is in fluid communication with the first heat dissipation device. The second heat dissipation device receives the working liquid from the first heat dissipation device. The fan is located near a side of the first heat dissipation device and a side of the second heat dissipation device. The fan produces airflow to the first heat dissipation device and the second heat dissipation device. Consequently, the heat of the working liquid within the first heat dissipation device and the second heat dissipation device is dissipated to surroundings through the airflow. Moreover, a cooling loop is defined by the liquid pump, the main liquid cooling head, the first heat dissipation device and the second heat dissipation device collaboratively.

In an embodiment, the first heat dissipation device and the second heat dissipation device are connected with each other through an elbow, and the working liquid within the first heat dissipation device flows to the second heat dissipation device through the elbow. There is an angle between the first heat dissipation device and the second heat dissipation device.

In an embodiment, the first heat dissipation device and the second heat dissipation device are liquid cooling radiators. The first heat dissipation device, the second heat dissipation device and the elbow are made of a metallic material. Alternatively, the first heat dissipation device and the second heat dissipation device are made of a metallic material and the elbow is made of a rubbery material.

In an embodiment, the fan is a centrifugal fan. The first heat dissipation device, the second heat dissipation device and the centrifugal fan are coplanar. The first heat dissipation device and the second heat dissipation device are arranged along a centrifugal direction of the centrifugal fan. The centrifugal fan produces the airflow to the first heat dissipation device and the second heat dissipation device.

In an embodiment, the first heat dissipation device and the second heat dissipation device are perpendicular to each other.

In an embodiment, the liquid cooling system further includes a first pipe, a second pipe and a third pipe. Two ends of the first pipe are respectively connected with the liquid pump and the main liquid cooling head. Consequently, the liquid pump and the main liquid cooling head are in fluid communication through the first pipe. Two ends of the second pipe are respectively connected with the main liquid cooling head and the first heat dissipation device. Consequently, the main liquid cooling head and the first heat dissipation device are in fluid communication through the second pipe. Two ends of the third pipe are respectively connected with the second heat dissipation device and the liquid pump. Consequently, the second heat dissipation device and the liquid pump are in fluid communication through the third pipe.

In an embodiment, the liquid cooling system further includes a first three-way connector, a second three-way connector and an auxiliary liquid cooling head. The first three-way connector is in communication with the first pipe and an inlet of the auxiliary liquid cooling head. Consequently, a first portion of the working liquid in the first pipe is guided to the auxiliary liquid cooling head through the first three-way connector and a second portion of the working liquid flows to the main liquid cooling head along the first pipe. The second three-way connector is in communication with the second pipe and an outlet of the auxiliary liquid cooling head. Consequently, the working liquid in the auxiliary liquid cooling head is guided to the second pipe through the second three-way connector and mixed with the second portion of the working liquid from the main liquid cooling head.

From the above descriptions, the present invention provides a liquid cooling system with at least two heat dissipation devices. In accordance with the present invention, the heat dissipating area is expanded and the hot airflow is not very concentrated. The fan produces airflow to the heat dissipation devices at different positions in order to increase the efficiency of dissipating the hot airflow. The liquid cooling system is capable of cooling the main liquid cooling head. In case that the liquid cooling system further comprises two three-way connectors and an auxiliary liquid cooling head, the main liquid cooling head and the auxiliary liquid cooling head are connected with each other through the two three-way connectors. Under this circumstance, the liquid cooling system can simultaneously cool the main liquid cooling head and the auxiliary liquid cooling head. Consequently, the space utilization is further enhanced.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic top view illustrating a liquid cooling system with multiple heat dissipation devices according to a first embodiment of the present invention; and

FIG. 2 is a schematic top view illustrating a liquid cooling system with multiple heat dissipation devices according to a second embodiment of the present invention.

### DETAILED DESCRIPTION OF THE PREFERRED EMBODIMENT

In this context, the term “liquid cooling system” is a loop that is composed of plural components or devices in series. A working liquid flows through the loop to facilitate heat transfer and heat dissipation. When the liquid cooling system is in contact with an external heat source (e.g., an electronic device), the heat exchange between the liquid cooling system and the heat source is established. The heat from the electronic device is carried away by the working liquid. Consequently, the temperature of the heat source is decreased.

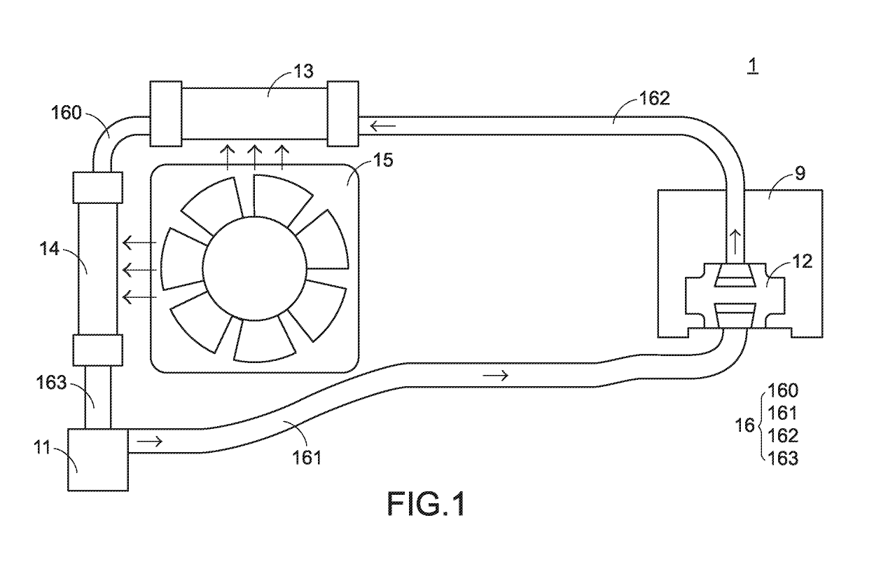

FIG. 1 is a schematic top view illustrating a liquid cooling system with multiple heat dissipation devices according to a first embodiment of the present invention. For succinctness, only two heat dissipation devices are shown in the drawings. It is noted that the number of the heat dissipation devices is at least two. In this embodiment, the liquid cooling system 1 comprises a liquid pump 11, a main liquid cooling head 12, a first heat dissipation device 13, a second heat dissipation device 14 and a fan 15. The liquid pump 11, the main liquid cooling head 12, the first heat dissipation device 13 and the second heat dissipation device 14 are in communication with each other through a piping system 16 so as to define a cooling loop. The piping system 16 will be described later. Moreover, a working liquid flows through the cooling loop. As the working liquid flows through the cooling loop, the purpose of transferring and dissipating the heat is achieved.

The piping system 16 comprises an elbow 160, a first pipe 161, a second pipe 162 and a third pipe 163. The first heat dissipation device 13 and the second heat dissipation device 14 are in fluid communication through the elbow 160. Consequently, the working liquid flows from the first heat dissipation device 13 to the second heat dissipation device 14 through the elbow 160. The elbow 160 is bent at an angle. The two ends of the elbow 160 are connected with the first heat dissipation device 13 and the second heat dissipation device 14, respectively. Consequently, the first heat dissipation device 13 and the second heat dissipation device 14 are not in parallel with each other. That is, there is an angle between the first heat dissipation device 13 and the second heat dissipation device 14, and the first heat dissipation device 13 and the second heat dissipation device 14 are separated from each other by a specified distance. The fan 15 is located near a side of the first heat dissipation device 13 and a side of the second heat dissipation device 14. Moreover, the fan 15 produces airflow toward the first heat dissipation device 13 and the second heat dissipation device 14. Since there is an angle between the first heat dissipation device 13 and the second heat dissipation device 14 and the first heat dissipation device 13 and the second heat dissipation device 14 are located at different positions, the first heat dissipation device 13 and the second heat dissipation device 14 are located beside different sides of the fan 15. Under this circumstance, the space for dissipating heat is increased, and the hot airflow around the first heat dissipation device 13 and the second heat dissipation device 14 can be exhausted to the surroundings more easily. Moreover, since the fan 15 produces the airflow to the first heat dissipation device 13 and the second heat dissipation device 14 along two directions, the heat of the working liquid in the first heat dissipation device 13 and the second heat dissipation device 14 can be dissipated to the surroundings more efficiently.

In an embodiment, the first heat dissipation device 13 and the second heat dissipation device 14 are perpendicular to each other, and the fan 15 is a centrifugal fan. Moreover, the first heat dissipation device 13, the second heat dissipation device 14 and the centrifugal fan 15 are substantially coplanar. Moreover, the first heat dissipation device 13 and the second heat dissipation device 14 are arranged along a centrifugal direction of the centrifugal fan. Consequently, the centrifugal fan 15 produces the airflow to the first heat dissipation device 13 and the second heat dissipation device 14. Since the first heat dissipation device 13 and the second heat dissipation device 14 are oriented along two different directions and the centrifugal fan 15 produces the airflow at 360 degrees, the heat dissipating efficiency of the liquid cooling system 1 is increased. Moreover, since the space utilization of the liquid cooling system 1 is enhanced, the overall liquid cooling system 1 is slim. In another embodiment, the fan 15 is replaced by two axial-flow fans. These two axial-flow fans are perpendicular to each other. Moreover, the two axial-flow fans produce the airflow to first heat dissipation device 13 and the second heat dissipation device 14, respectively.

The two ends of the first pipe 161 are connected with the liquid pump 11 and the main liquid cooling head 12, respectively. Consequently, the liquid pump 11 and the main liquid cooling head 12 are in fluid communication through the first pipe 161. The working liquid in the liquid pump 11 is driven to the main liquid cooling head 12 by the liquid pump 11. When the heat from an electronic component 9 is received by the main liquid cooling head 12, the temperature of the main liquid cooling head 12 is increased. When the working liquid flows to the main liquid cooling head 12, the heat is transferred from the main liquid cooling head 12 to the working liquid. The two ends of the second pipe 162 are connected with the main liquid cooling head 12 and the first heat dissipation device 13, respectively. Consequently, the main liquid cooling head 12 and the first heat dissipation device 13 are in fluid communication through the second pipe 162. The working liquid with the increased temperature and from the main liquid cooling head 12 is received by the first heat dissipation device 13. The two ends of the third pipe 163 are connected with the second heat dissipation device 14 and the liquid pump 11, respectively. Consequently, the second heat dissipation device 14 and the liquid pump 11 are in fluid communication through the third pipe 163. After the working liquid leaves from the second heat dissipation device 14, the temperature of the working liquid is decreased. Then, the working liquid with the decreased temperature is pumped to the main liquid cooling head 12 by the liquid pump 11 again. Meanwhile, the working liquid flows through the cooling loop once.

In an embodiment, the first heat dissipation device 13 and the second heat dissipation device 14 are liquid cooling radiators. The liquid cooling radiator comprises at least one channel and plural fins (not shown). Consequently, the liquid cooling radiator has a large heat dissipating area for efficiently exchange heat with the surroundings. In an embodiment, the first heat dissipation device 13, the second heat dissipation device 14 and the elbow 160 are made of a metallic material, and the two ends of the elbow 160 are welded onto the first heat dissipation device 13 and the second heat dissipation device 14. In another embodiment, the first heat dissipation device 13 and the second heat dissipation device 14 are made of a metallic material, and the elbow 160 is made of a rubbery material. Moreover, the two ends of the elbow 160 are coupled with the first heat dissipation device 13 and the second heat dissipation device 14, respectively. The above two embodiments are feasible.

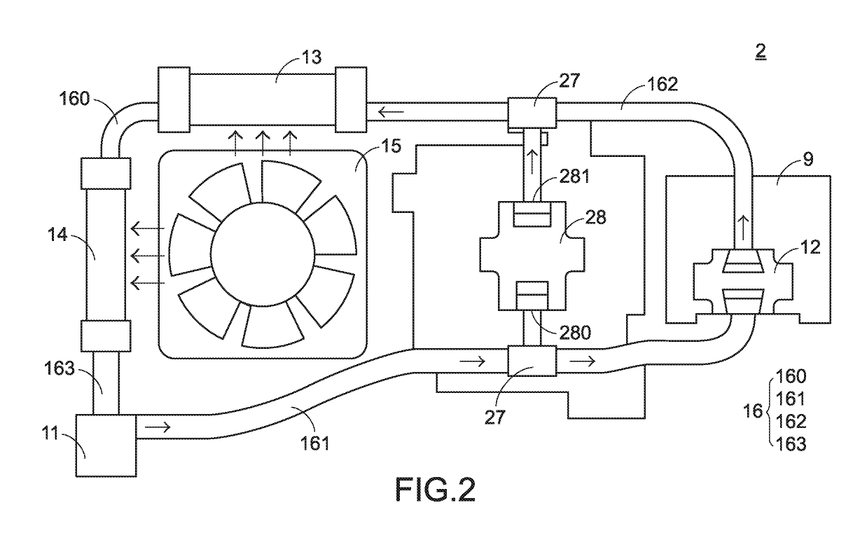

FIG. 2 is a schematic top view illustrating a liquid cooling system with multiple heat dissipation devices according to a second embodiment of the present invention. Like the first embodiment, the liquid cooling system 2 also comprises a liquid pump 11, a main liquid cooling head 12, a first heat dissipation device 13, a second heat dissipation device 14 and a fan 15. The liquid pump 11, the main liquid cooling head 12, the first heat dissipation device 13 and the second heat dissipation device 14 are in communication with each other through a piping system 16 so as to define a cooling loop. Moreover, a working liquid flows through the cooling loop. As the working liquid flows through the cooling loop, the purpose of transferring and dissipating the heat is achieved.

In comparison with the first embodiment, the liquid cooling system 2 of this embodiment further comprises two three-way connectors 27 and an auxiliary liquid cooling head 28. The first three-way connector 27 of the two three-way connectors 27 is in communication with the first pipe 161 and an inlet 280 of the auxiliary liquid cooling head 28. Consequently, a portion of the working liquid in the first pipe 161 is guided to the auxiliary liquid cooling head 28 through the first three-way connector 27, and the remaindering portion of the working liquid flows to the main liquid cooling head 12 along the first pipe 161. A second three-way connector 27 of the two three-way connectors 27 is in communication with the second pipe 162 and an outlet 281 of the auxiliary liquid cooling head 28. Consequently, the working liquid in the auxiliary liquid cooling head 28 is guided to the second pipe 162 through the second three-way connector 27 and mixed with the working liquid from the main liquid cooling head 12. Under this circumstance, the main liquid cooling head 12 and the auxiliary liquid cooling head 28 are connected with each other in parallel. In this embodiment, the components or devices for constructing a single cooling loop (e.g., the liquid pump 11, the first heat dissipation device 13 and the second heat dissipation device 14) are used to simultaneously cool two or more than two liquid cooling heads (e.g., the main liquid cooling head 12 and the auxiliary liquid cooling head 28). Since the components and devices are saved, the volume of the liquid cooling system is reduced and the space utilization is enhanced.

From the above descriptions, the present invention provides a liquid cooling system with at least two heat dissipation devices. In accordance with the present invention, the heat dissipating area is expanded and the hot airflow is not very concentrated. The fan produces airflow to the heat dissipation devices at different positions in order to increase the efficiency of dissipating the hot airflow. The liquid cooling system is capable of cooling the main liquid cooling head. In case that the liquid cooling system further comprises two three-way connectors and an auxiliary liquid cooling head, the main liquid cooling head and the auxiliary liquid cooling head are connected with each other through the two three-way connectors. Under this circumstance, the liquid cooling system can simultaneously cool the main liquid cooling head and the auxiliary liquid cooling head. Consequently, the space utilization is further enhanced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

1. A liquid cooling system with multiple heat dissipation devices, a working liquid flowing through the liquid cooling system to facilitate heat dissipation, the liquid cooling system comprising:
a liquid pump;
a main liquid cooling head in fluid communication with the liquid pump, wherein the working liquid within the liquid pump is pumped into the main liquid cooling head by the liquid pump, so that the working liquid within the main liquid cooling head exchanges heat with the main liquid cooling head;
a first heat dissipation device in fluid communication with the main liquid cooling head, wherein the first heat dissipation device receives the working liquid from the main liquid cooling head;
a second heat dissipation device in fluid communication with the first heat dissipation device, wherein the second heat dissipation device receives the working liquid from the first heat dissipation device, the first heat dissipation device and the second heat dissipation device are not in parallel with each other, and the first heat dissipation device and the second heat dissipation device are liquid cooling radiators; and
a fan located near a side of the first heat dissipation device and a side of the second heat dissipation device, wherein the fan produces airflow to the first heat dissipation device and the second heat dissipation device, so that the heat of the working liquid within the first heat dissipation device and the second heat dissipation device is dissipated to surroundings through the airflow,
wherein a cooling loop is defined by the liquid pump, the main liquid cooling head, the first heat dissipation device and the second heat dissipation device collaboratively.

2. The liquid cooling system according to claim 1, wherein the first heat dissipation device and the second heat dissipation device are connected with each other through an elbow, and the working liquid within the first heat dissipation device flows to the second heat dissipation device through the elbow, wherein there is an angle between the first heat dissipation device and the second heat dissipation device.

3. The liquid cooling system according to claim 2, wherein the first heat dissipation device, the second heat dissipation device and the elbow are made of a metallic material, or the first heat dissipation device and the second heat dissipation device are made of a metallic material and the elbow is made of a rubbery material.

4. The liquid cooling system according to claim 2, wherein the fan is a centrifugal fan, wherein the first heat dissipation device, the second heat dissipation device and the centrifugal fan are coplanar, the first heat dissipation device and the second heat dissipation device are arranged along a centrifugal direction of the centrifugal fan, and the centrifugal fan produces the airflow to the first heat dissipation device and the second heat dissipation device.

5. The liquid cooling system according to claim 4, wherein the first heat dissipation device and the second heat dissipation device are perpendicular to each other.

6. The liquid cooling system according to claim 1, wherein the liquid cooling system further comprises a first pipe, a second pipe and a third pipe, wherein two ends of the first pipe are respectively connected with the liquid pump and the main liquid cooling head, so that the liquid pump and the main liquid cooling head are in fluid communication through the first pipe, wherein two ends of the second pipe are respectively connected with the main liquid cooling head and the first heat dissipation device, so that the main liquid cooling head and the first heat dissipation device are in fluid communication through the second pipe, wherein two ends of the third pipe are respectively connected with the second heat dissipation device and the liquid pump, so that the second heat dissipation device and the liquid pump are in fluid communication through the third pipe.

7. The liquid cooling system according to claim 6, wherein the liquid cooling system further comprises a first three-way connector, a second three-way connector and an auxiliary liquid cooling head, wherein the first three-way connector is in communication with the first pipe and an inlet of the auxiliary liquid cooling head, so that a first portion of the working liquid in the first pipe is guided to the auxiliary liquid cooling head through the first three-way connector and a second portion of the working liquid flows to the main liquid cooling head along the first pipe, wherein the second three-way connector is in communication with the second pipe and an outlet of the auxiliary liquid cooling head, so that the working liquid in the auxiliary liquid cooling head is guided to the second pipe through the second three-way connector and mixed with the second portion of the working liquid from the main liquid cooling head.
